(19) United States
(12) Patent Application Publication
(10) Pub. No.: US 2012/0132252 A1
(43) Pub. Date: May 31, 2012

(54) TRANSPORT ROLLER FOR TRANSPORTING ARTICLES

(76) Inventors: Jingjia Ji, Jiangsu (CN); Liping Chen, Jiangsu (CN); Hongqiang Qian, Jiangsu (CN); Zhengrong Shi, Jiangsu (CN)

(21) Appl. No.: 13/321,167

(22) PCT Filed: May 26, 2009
(86) PCT No.: PCT/CN2009/000585

§ 371 Date: Feb. 10, 2012

(51) Int. Cl. H01L 31/042; C25D 17/06; C25D 17/12; B65G 39/06; B65G 39/04

(52) U.S. Cl. 136/244; 198/780; 198/617; 204/202

(57) ABSTRACT

A transport roller for transporting articles comprises a spindle (3) and a coil (5) on the spindle (3). The coil (5) comprises a flexible central section (17), and a first end section (13) and a second end section (15) that are affixed at two opposite sides of the flexible central section (17) to the spindle (3).

### TECHNICAL FIELD

The present invention relates to transport mechanisms, and in particular, to rollers for transporting articles.

### BACKGROUND

Inline processes have found widespread industrial uses, for example, in manufacturing solar cells. In such processes, articles are continuously moved along a relatively linear path to different baths or stages in which the articles receive different treatments, including wet-chemical treatments. As an example, an article such as a substrate or wafer can be chemically treated by both alkaline (e.g., NaOH) and acid (e.g., HF) solutions in different wet baths of the inline process. The substrate or wafer may be etched, cleaned, dried, or plated in different baths or stages of the process.

During transport in a wet bath, a substrate or wafer may float up and down or shift left and right away from the direction of transportation. Such movement may occur as a result of turbulence caused by chemical reactions, or as a result of the interaction between the substrate or wafer and its surroundings. The substrate also may be vibrated, for example, as a result of blow-drying. To reduce and control unintended motion in an inline process, a substrate or wafer may be guided by roller pairs, which comprise, for example, top transport rollers and bottom transport rollers. The top transport rollers and bottom transport rollers may act together to hold the substrates in place while being transported in the inline process. Typically the rollers have solid cylindrical surfaces.

With the advent of many new technologies, substrates have become thinner. For example, in the photovoltaic solar module industry, substrates or wafers may have a thickness below 200 μm, and may be brittle and easily broken under existing techniques. Similarly, soft substrates and wafers such as soft printed circuit boards are susceptible to be damaged under existing techniques. For example, if contacted too firmly by a top transport roller, a thin rigid substrate or wafer may break. On the other hand, if contacted too lightly or not contacted by the top transport roller, the substrate or wafer may not move properly. Likewise, for soft substrates or wafers, hard pressure from a transport top roller can create marks or surface damage.

Transport rollers sometimes act as electrical contacts in an inline process involving electroplating. Due to movement of the top transport rollers and substrates or wafers, electrical contact between the top rollers and the substrates or wafers can be inconsistent or interrupted. In some situations the rollers may use rudder pieces intended to maintain constant pressure on the substrates. However, misalignments between the rudder pieces of top and bottom rollers may cause damage to substrates. Further, the rudder pieces typically do not provide good electrical contacts in plating applications.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF DRAWINGS

In the drawings:

FIG. 1 illustrates an example transport roller;

FIG. 2A, FIG. 2B, and FIG. 2C illustrate example non-displaced and displaced states of an example transport roller relative to a spindle;

FIG. 3 illustrates an example configuration in which an example transport roller is electrically connected to an example electric current source or sink;

FIG. 4A and FIG. 4B illustrate example configurations in which two example coils are on an example spindle;

FIG. 5A and FIG. 5B illustrate example configurations in which top roller groups and bottom rollers groups are used to transport an article;

FIG. 6 illustrates an example configuration in which top roller groups and bottom roller groups transport an article into and out of a basin in which the article receives a treatment.

### SUMMARY OF THE DISCLOSURE

The disclosure provides techniques related to transport rollers that use flexible coils or springs to engage articles for transportation. Pressure on articles asserted by a transport roller can be adjusted by altering characteristics of the springs. The coils may be flexible and coil windings provide multiple contact points, so that pressure can be distributed evenly on the entire upper or lower surface of a wafer or substrate. The springs may provide multiple electric contact points for electroplating a wafer or substrate; the number of contact points is adjustable. The contacts provide secure, even, and consistent electric connection to one or both of the upper and lower surfaces of the wafer or substrate in many applications.

In an embodiment, a transport roller comprises a spindle and a coil on the spindle; the coil comprises a flexible central section; the coil comprises a first end section and a second end section that are affixed at two opposite sides of the flexible central section to the spindle. In some embodiments, only the flexible central section, but not other sections of the coil, is used to physically engage or contact an article for transportation.

The first end section and the second end section may be affixed to the spindle by a longitudinally adjustable fixing device. Additionally or alternatively, the first end section and the second end section may be affixed to the spindle by fixing devices having annular collars that encircle the first end section and the second end section.

In some embodiments, the coil comprises a wire spring. In various embodiments, the coil may be constructed using various types of materials including electrical conductors and electrical insulators.

In some embodiments, the coil further comprises a first tapered section and a second tapered section at opposite sides of the flexible central section. The first tapered section and the second tapered section join the flexible central section to the first end section and the second end section. In some embodiments where the spindle and the flexible central section have circular shapes, the flexible central section has an internal diameter that is larger than an external diameter of the spindle. As a result, the flexible central section may be in a concentrically aligned position relative the spindle. In this concentric position, the flexible central section does not touch the spindle because of the difference in the internal diameter of the flexible central section and the external diameter of the spindle. The space between the flexible central section and the spindle may be in the shape of a concentric ring. When the flexible central section engages an article for transportation, buoyancy and disturbances caused by sources other than the coil may cause variations in the forces exerted on the article. The variations in the forces exerted on the article in turn cause variations in a net external force exerted on the flexible central section. The flexible central section may move off from the concentrically aligned position relative to the spindle, in reaction to the variations in the net external force. When the flexible central section is off the concentric position, the space between the flexible central section and the spindle may be in an irregular shape other than the concentric ring shape as previously mentioned.

In some embodiments, the flexible central section has an external diameter that is larger than both a first external diameter of the first end section and a second external diameter of the second end section.

In some embodiments, the coil is electrically conductive. For example, the coil may be made of a material that is electrically conductive in the environment in which an article is transported. The coil may be electrically coupled to an electric current source or sink in various applications. One application may be a stage of an inline process in which the article is to be electroplated while submerged in a solution. The electric current source or sink may be direct-current (DC), or alternating current (AC) current and may include DC bias.

In some embodiments, the coil is electrically non-conductive. For example, the coil may be made of a material that is not electrically conductive in the environment in which an article is transported. The coil may be electrically insulated from any electric current source or sink, depending on the application. One application may be a stage of the inline process in which the article is to be transported between two other stages in which the article is to receive different treatments other than electroplating.

In various embodiments, the flexible central section may have a width dimension different than that of a surface of an article to be transported using the roller.

In some embodiments, each winding in the flexible central section may contribute one discrete contact area among a plurality of discrete contact areas between the flexible central section and the article to be transported. In an embodiment, the flexible central section comprises three or more discrete contact areas. In a particular embodiment, a longitudinally adjustable fixing device may also be configured to adjust the number of discrete contact areas of the flexible central section.

In some embodiments, the same transport roller may further comprise one or more second coils each on the spindle. In an embodiment, at least one of the one or more second coils comprises a second flexible central section. A longitudinal distance between the coil and at least one of the one or more second coils may be adjustable. In some embodiments, the coil is affixed to but removable from the spindle.

Various embodiments include a method, a system, an assembly, or an apparatus that provides or implements embodiments as described above. For example, in some embodiments, a transport apparatus may comprise a frame, and a plurality of transport rollers spaced apart and rotatably mounted in the frame. At least one transport roller in the plurality of transport rollers is the transport roller as described above.

In some embodiments, a method comprises providing a transport apparatus as described, and transporting an article using the transport rollers.

In some embodiments, the methods, systems, assemblies, or apparatus as described herein may be used in an inline process in which an article receives one or more treatments while transported. In some embodiments, methods, systems, assemblies, or apparatus as described herein may be used to electroplate substrates or wafers.

Various embodiments also include products that are produced using some embodiments of the methods. Subtracts may be rigid or soft, may be ceramic, plastic or metal. Example products include solar cells, solar panels, and solar modules.

### DETAILED DESCRIPTION OF EMBODIMENTS

In the following description, for the purposes of explanation, numerous specific details are set forth in order to provide a thorough understanding of the present invention. It will be apparent, however, that embodiments may be made without these specific details. In other instances, well-known structures and devices are shown in block diagram form in order to avoid unnecessarily obscuring embodiments.

Example Transport Roller

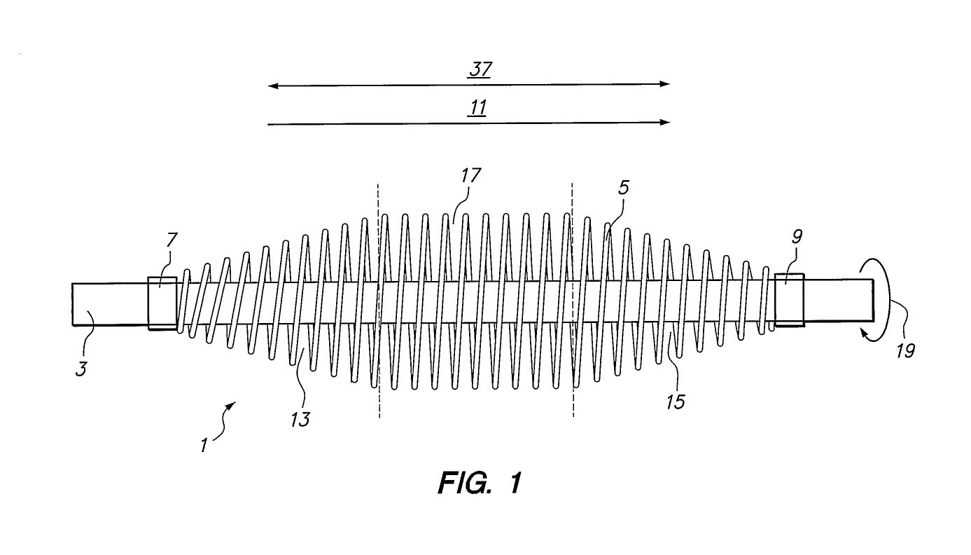

FIG. 1 illustrates an example transport roller. In the example of FIG. 1 a transport roller 1 comprises a coil 5 on a spindle 3. The coil 5 is removably affixed to the spindle 3 using a first fixing element 7 and a second fixing element 9. In the example of FIG. 1, spacing between neighboring windings in the flexible central section 17 is even. In other embodiments, non-even spacing may be used.

In one embodiment, coil 5 may comprise a first tapered section 13, a second tapered section 15, and a flexible central section 17. The first tapered section 13 may be symmetric with the second tapered section 15. In other embodiments, sections 13, 15 are asymmetric. The flexible central section 17 is located between the first tapered section 13 and the second tapered section 15, and may be in the geometric center of the coil 5.

FIG. 1 shows a side elevation view of the transport roller 1. In an embodiment, individual windings of the central section 17 may have approximately the same diameter, so that imaginary lines connecting outermost edge points of the coil 5 form a straight contour or profile. In an embodiment, at least a portion of the flexible central section 17 is exposed and can directly contact a portion of a surface of an article. The article may comprise a substrate, wafer, or any other item, including non-planar items. In other embodiments, coil 5 may have a contour that is not straight. In some embodiments, for example, the tapered sections may have an arcuate or curved profile.

FIG. 1 shows the coil 5 having the first tapered section 13, the second tapered section 15, and the flexible central section 17 with equal linear sizes. In other embodiments, the relative and absolute dimensions of the sections 13, 15, 17 of coil 5 may vary. In general, the drawings show examples and are not drawn to scale.

In some embodiments, the flexible central section 17 forms two parallel straight lines in an elevation or section view. In other embodiments, non-parallel straight lines may be used in the profile of the coil 5 as the central section 17 is flexible. For example, some portions of the central section 17 may momentarily disengage from an article that is transported by the transport roller, while other portions of the central section fully engage the article.

In some embodiments, spacing between adjacent windings of the coil 5 may be adjustable. To adjust spacing, one or both of the first fixing element 7 and the second fixing element 9 may be movable along the longitudinal direction 11 of the spindle 3, while the other of the two sections is fixed. In some embodiments, both fixing elements 7, 9 may be movable along the longitudinal direction 11. In some embodiments, the adjustment of spacing between windings of the coil 5 may be made before, at the same time as, or after the transport roller 1 has been deployed in a transport system in a field.

Displacements of an Example Flexible Central Section

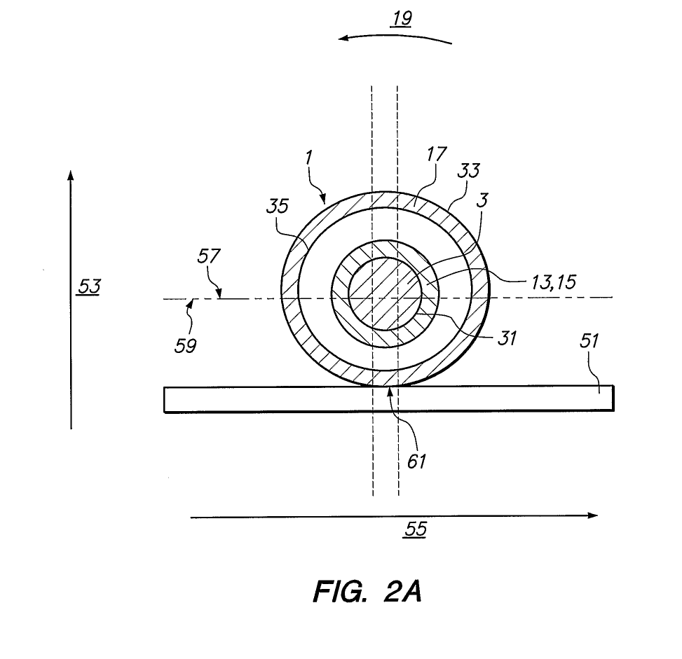

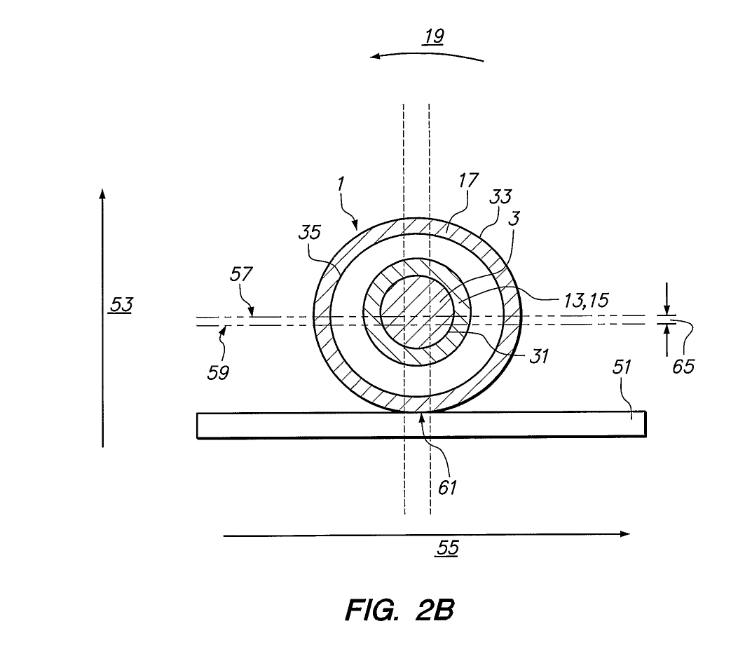

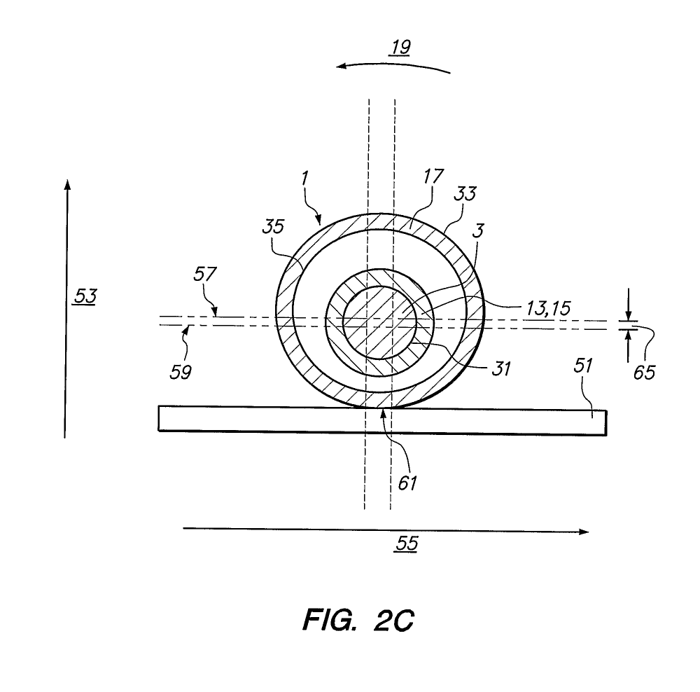

FIG. 2A, FIG. 2B, FIG. 2C illustrate example non-displaced and displaced states of an example transport roller relative to a spindle. FIG. 2A, FIG. 2B, FIG. 2C show different sectional views of the transport roller 1 with an article 51 in various displacement states. In FIG. 2A, FIG. 2B, FIG. 2C, transport roller 1 is viewed in longitudinal direction 11 of FIG. 1.

FIG. 2A shows a view of the transport roller 1 with the article 51 in a non-displaced state. FIG. 2B shows a view of the transport roller 1 with the article 51 in a displaced state in which the flexible central section 17 is pushed up along a normal direction 53, which is vertical to both the longitudinal direction 11 and a transportation direction 55. FIG. 2C shows a view of the transport roller 1 with the article 51 in another displaced state in which the flexible central section 17 is sagged down along the normal direction 53 to maintain the physical contact with the article.

In some embodiments, flexibility of the central section 17 derives from flexibility of the coil 5. For example, the coil 5 may be compressed or stretched along its longitudinal direction 11. The longitudinal spring force from the coil 5 related to the longitudinal compression and stretch of the coil 5 may be characterized by a first effective spring constant. The coil 5 may also move up and down along the normal direction 53. The vertical spring force from the coil 5 related to the pushing up and sagging down of the coil 5 may be characterized by a second effective spring constant. The first effective spring constant and the second effective spring constant are not necessarily equal.

In some embodiments, the spindle 3 may be a cylinder having an outer circumference 31 equal to the innermost circle as depicted in FIG. 2A, FIG. 2B and FIG. 2C. A spindle center plane 57 bisects spindle 3 along longitudinal direction 11. In some embodiments, central section 17 of coil 5 may be schematically represented as a cylindrical ring in the views of FIG. 2A, FIG. 2B FIG. 2C. The exterior and interior circumferences (33 and 35 respectively) of the cylindrical ring, which are the same as the exterior and interior circumferences of the flexible central section 17, are the two outermost circles depicted in FIG. 2A, FIG. 2B and FIG. 2C. A coil center plane 59 bisects the imaginary cylindrical ring along the longitudinal direction 11.

Moving an Article Using Rollers

In a transportation process such as an inline process, the transport roller 1 may be placed in physical contact with an article that is transported for an interval of time. The particular time may depend on the length of the article and the transportation speed at the point of the transport roller. The flexible central section 17 may physically contact an upper surface of the article as the article is transported in the inline process during that interval of time, resulting in frictional contact 61.

The frictional contact 61 may occur at different portions of flexible central section 17 at different times as the transport roller rotates. When transport roller 1 is driven by spindle 3 rotating along rotational direction 19, transport roller 1 may exert a first force through the frictional contact 61 on article 51 along transportation direction 55. The first force can overcome the resistive force exerted on the article from various other sources. The resistive force from the other sources may tend to slow down or prevent the article from moving in the transportation direction 55. The resistive force may arise from viscosity or turbulence caused by a liquid or gas in a bath in which the article 51 is floated or submerged. Alternatively, the resistive force may arise from the surrounding air.

Through the same frictional contact 61, the transport roller 1 also exerts a second force anti-parallel with a normal direction 53. The second force keeps the flexible central section 17 engaged in physical contact with the surface of the article 51. When the transport roller 1 is in a displaced state, so that the flexible central section 17 is pushed up or down along the normal direction 53 from its non-displaced state, the transport roller exerts a vertical spring force on article 51. The spring force may comprise all or some of the second force. The magnitude of the spring force may be proportional to a magnitude of a displacement from the first centerline 57 to the second centerline 59, and may depend on the second effective spring constant.

The vertical spring force may be anti-parallel to, and proportional in magnitude to the magnitude of, a positive displacement 63 of FIG. 2C or negative displacement 65 of FIG. 2B from the first centerline 57 to the second centerline 59. As used herein, the term “vertical” means parallel or anti-parallel to the normal direction 53.

In some embodiments, the mass, weight or gravitational force of the transport roller may also provide some or all of the second force. The composition of this second force may change depending on the magnitude of displacement from the first centerline 57 to the second center line 59, the mass of the coil, or other factors. In an embodiment, the mass of the transport roller and the vertical spring force both contribute to the second force.

Because the vertical spring force depends on the displacement, the second force is able to automatically react to, and thus adjust with, other forces that are exerted on the article 51 in the normal direction. For example, the second force may be exerted with a small magnitude if the article 51 is transported through a fluid that exerts a small buoyant force on the article. The second force may be exerted with a large magnitude if the article 51 is transported through a fluid that exerts a large buoyant force on the article. The exertion of the second force and the automatic adjustment of its magnitude are produced by the flexible nature of the coil 5, particularly central section 17, when the central section reacts to other forces that are exerted on the coil along the normal direction 53.

The second force may react to forces other than the buoyant force. Example forces may arise from transient disturbances in transportation. Because central section 17 is flexible, displacement from first centerline 57 to second centerline 59 can be automatically adjusted in response to disturbances. As a result, the second force, which is proportional in magnitude to the magnitude of the displacement and anti-parallel to the additional displacement caused by the disturbances, can exert an automatically adjusted force on the article 51 to resist the disturbances. This continuous balancing of forces by the second force reduces the possibility of excessive stress on article 51. Thus, even if article 51 is thin, brittle or soft, the article may suffer little physical damage in transportation, since flexible central section 17 can provide an automatic reactionary force with only a magnitude necessary to counter the other forces.

Through the same frictional contact 61, the transport roller may further exert a third force in a planar direction (37 of FIG. 1) that is vertical to both the transportation direction 55 and the normal direction 53. In some embodiments, at zero or more points in the transportation process, the planar direction 37 coincides with longitudinal direction 11. The third force, when exerted, helps keep article 51 from swinging left and right away from the transportation direction 55 in a plane formed by the transportation direction 55 and the planar direction 37.

For example, coil 5 may be longitudinally in an equilibrium state when not in physical contact with article 51. When transport roller 1 engages article 51 for transportation, the article may be pushed to left and right off the transportation direction 55 by various disturbances. When article 51 is moved off the transportation direction 55, coil 5 of the transport roller 1 may be longitudinally in a non-equilibrium state. In this non-equilibrium state, some windings of the flexible central section 17 may be longitudinally displaced in the same direction as the article 51 is pushed. The longitudinal displacement in the coil 5 produces the longitudinal spring force that will be exerted in the opposite direction to the direction of this longitudinal displacement. Therefore, in a non-equilibrium state, coil 5 may provide some or all of the third force in the form of a longitudinal spring force to help restore the article 51 to the transportation direction 55.

Other Example Configurations of a Transport Roller

In an embodiment, spindle 3 is a solid cylinder. In other embodiments, other shapes may be used and spindle 3 does not have to be a single component. For example, spindle 3 may comprise two or more components which may be cylindrical or non-cylindrical structures. In some embodiments, at least one component of the spindle 3 is stationary when transport roller 1 is transporting an article. In some embodiments, only some of the components of the spindle 3 are rotated by a driving mechanism. The rotatable components of the spindle 3 may drive the coil 5 to make movements through the first fixing element 7 and the second fixing element 9.

Coil 5 may be affixed to the spindle 3 using first fixing element 7 and second fixing element 9. In an embodiment, each of fixing element 7, 9 comprises a round collar that fits over spindle 3 and is affixed using a set screw, pin, clip, or other retainer. In other embodiments, other affixing configurations may be used. For example, one or both of the first fixing element 7 and the second fixing element 9 may be affixed in a removable manner. One or both of the fixing elements 7, 9 may slide along the spindle 3. Slots, guides, grooves, holes or keys may be configured for affixing the coil 5 to the spindle 3 so that the coil is retained on the spindle, but can flexibly urge an article in various directions as the article contacts the coil.

In an embodiment, spindle 3 has one coil 5. In other embodiments, two or more coils may be on spindle 3. In various embodiments, along longitudinal direction 11, flexible central section 17 may be longer, shorter, or the same as a width of the article 51.

To transport the article 51 over a certain linear distance in the transportation direction 55, one or more coils on the same spindle may engage the article at the same time. In other embodiments, one coil 5 may engage more than one article for transportation at the same time.

Example Electrical Connection

In some embodiments, coil 5 comprises wire windings. Coil 5 may be electrically conductive or non-conductive depending on the applications in which the transport roller 1 is used. In some embodiments, transport roller 1 is used in an electroplating application.

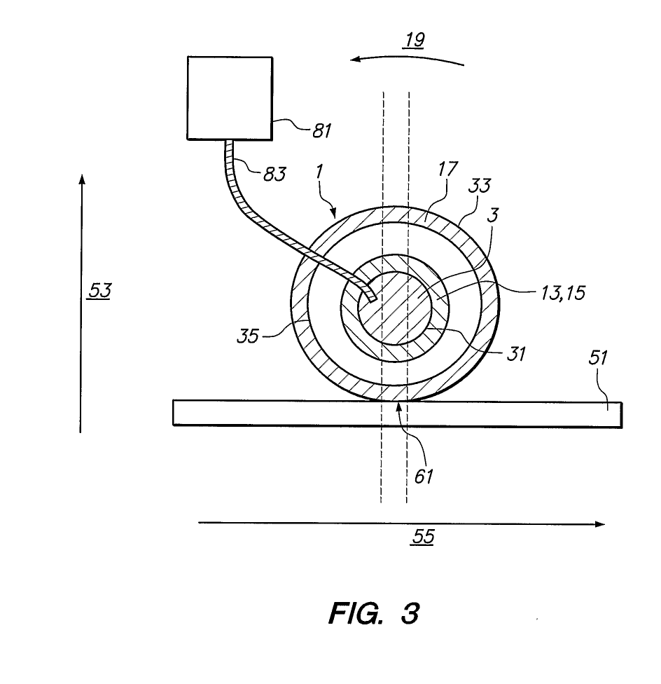

FIG. 3 illustrates an example configuration in which an example transport roller is electrically connected to an example electric current source or sink. In the example of FIG. 3, the flexible central section 17 of the coil 5 may be electrically connected to an electric current source or sink 81 and comprises electrically conductive windings. Coil 5 may be electrically connected to the spindle 3 or a component therein. Alternatively, a conductor may be coupled directly to a winding of the coil 5.

In an embodiment, a stationary component of spindle 3 is electrically connected to current source or sink 81 via an external electric connection 83. A rotatable component of spindle 3 may be electrically connected to the stationary component, or directly to the current source or sink 81. The rotational component of the spindle 3 may be electrically connected to the coil 5, or to the frictional contact 61 of the flexible central section 17. The surface of the article 51 that is in physical contact with the flexible central section 17 through the frictional contact 61 may be metallic or otherwise electrically conductive. When contacted by the central section 17, the surface may be electrically connected to the central section, to the electric connection 83, and to the electric current source or sink 81. When used in electroplating, the central section 17 of the transport roller 1 can draw or supply electric current from or to the surface of the article 51.

The central section 17 may comprise a large number of windings, each of which may provide an electric contact to the article 51. Thus, coil 5 may provide a large number of electric contacts with article 51 through the frictional contact 61. Unlike prior approaches, the number of the electric contacts between the article and the transport roller 1 produces a relatively evenly distributed electric potential field on or near the surface of the article 51. In various embodiments, the number of electric contacts through the frictional contact 61 may be two, three, or many more.

As used herein, the term “electric current source or sink” may refer to a power supply or any other arrangement in which an electric current can flow in or out via an external electric connection from the frictional contact of the transport roller. The current may come from an external electric device or by a process involving photovoltaic current generation.

Example Two-Coil Configurations

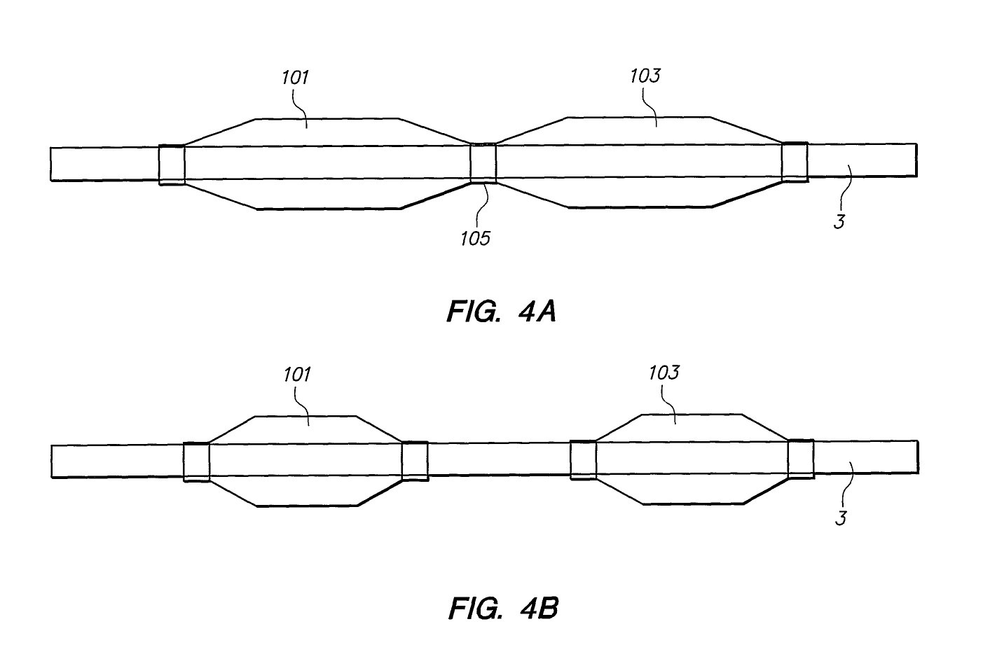

FIG. 4A and FIG. 4B illustrate example configurations in which two coils are on an example spindle.

FIG. 4A illustrates a first example configuration in which a first coil 101 and a second coil 103 are on the same spindle 3. One or both of coils 101, 103 of FIG. 4A may be the same as the coil 5 illustrated in FIG. 1, FIG. 2A, FIG. 2B, FIG. 2C, FIG. 3. In this example, the coils 101, 103 have a common section 105 at which one end of the coils is affixed to the spindle 3. Common section 105 may comprise the first fixing element 7 or the second fixing element 9 for the first coil 101. The common section 105 also may be either the first fixing element 7 or the second fixing element 9 for the second coil 103.

FIG. 4B illustrates a second example configuration in which the first coil 101 and the second coil 103 are on spindle 3. As in the first example configuration, in FIG. 4B, one or both of the coils 101, 103 may be the same as coil 5 illustrated in FIG. 1, FIG. 2A, FIG. 2B, FIG. 2C, FIG. 3. In this second example configuration, the coils 101, 103 do not share a common section as in FIG. 4A, but each coil has separate sections that are affixed to the spindle 3. The distance between the two coils 101, 103 can be adjusted in some embodiments.

In various embodiments, the senses of windings for the coils 101, 103 may be the same or different. In this context, the term “senses” refers to directions as determined by the right-hand grip rule. The coils 101, 103 may have different winding numbers and may have different physical properties such as material, hardness, or smoothness. In some embodiments, coils 101, 103 have the same exterior diameters while in other embodiments the coils have different exterior diameters. In some embodiments, coils 101, 103 have the same interior diameters while in other embodiments the coils have different interior diameters. In some embodiments, only the flexible central section of one of the coils 101, 103 is electrically connected to an electric current source or sink 81 while in other embodiments, both flexible central sections are electrically connected to the electric current source or sink. In other embodiments, both flexible central sections of the coils 101, 103 are not electrically connected to an electric current source or sink.

Example Roller Groups

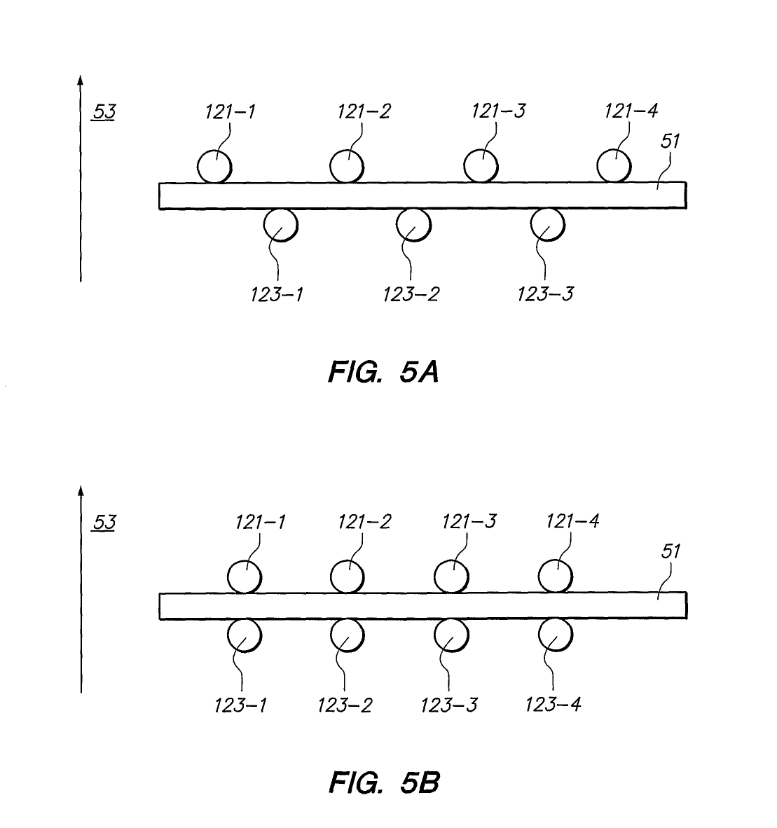

FIG. 5A and FIG. 5B illustrate example configurations in which top roller groups and bottom roller groups are used to transport an article. FIG. 5A illustrates an example configuration in which the article 51, in the form of an object with two substantially flat upper and lower surfaces, is transported by a plurality of roller groups. As used herein, a roller group refers to an assembly that may comprise one, two, or more transport rollers sharing the same spindle.

In FIG. 5A, a configuration comprises top roller groups 121-1, 121-2, 121-3, 121-4 and bottom roller groups 123-1, 123-2, 123-3. At least one of the roller groups comprises a transport roller such as 1 of FIG. 1. In this example configuration, the distance between any two neighboring top roller groups may be adjusted. The distance may be measured by the centers of their respective spindles, for example. Likewise, the distance between any two neighboring bottom roller groups may also be adjusted. In FIG. 5A, some or all of the top roller groups may not be aligned with any of the bottom roller groups along the normal direction 53.

FIG. 5B illustrates an alternative example configuration in which roller groups transport the article 51 with upper and lower surfaces. Each of top roller groups 121-1 through 121-4 and bottom roller groups 123-1 through 123-4 may comprise one, two, or more transport rollers sharing a respective spindle. At least one of the roller groups comprises a transport roller such as 1 of FIG. 1.

In the configuration of FIG. 5B, the distance between any two neighboring top roller groups may be adjusted. Likewise, the distance between any two neighboring bottom roller groups may also be adjusted. Further, one or more of the top roller groups may be aligned with corresponding bottom roller groups along the normal direction 53. In some embodiments, zero or more of the transport rollers in the top roller groups 121 or in the bottom roller groups 123 are formed as shown in FIG. 1.

When a transport roller 1 is used in a bottom roller group, the mass of coil 5 may reduce the second force. However, since the second force may comprise the vertical spring force generated from the displacement of the coil 5, the second force is still automatically responsive to other forces that are exerted on the article 51 in the normal direction. This second force can still be used to engage the article 51 during the movement and to dampen impacts from sudden changes or disturbances in other forces that exert on the article 51.

Example Use of Rollers in an Inline Process

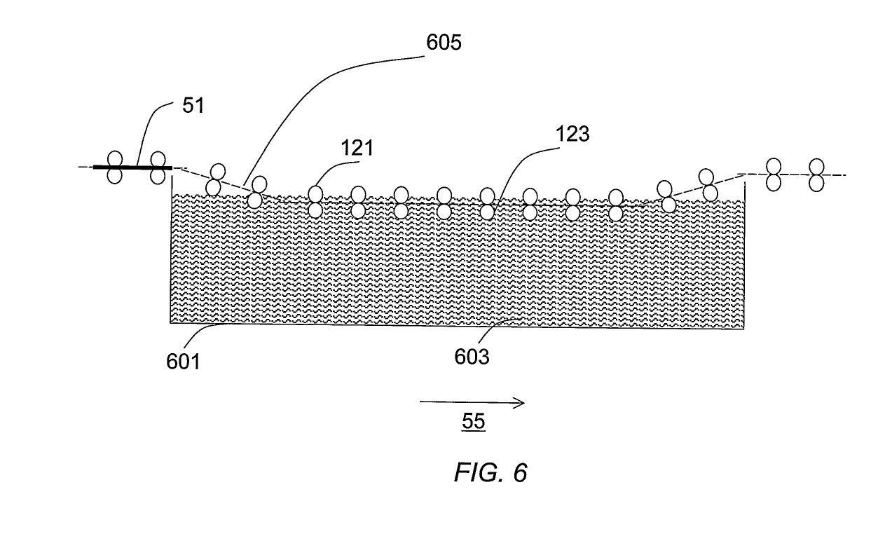

FIG. 6 illustrates an example configuration in which top roller groups and bottom roller groups transport an article into and out of a basin in which the article receives a treatment. FIG. 6 illustrates an example portion of an inline process in which the article 51, comprising two substantially flat upper and lower surfaces, is transported through a plurality of top roller groups 121 and 123 along a transport trajectory 605. In an embodiment, a tangent of trajectory 605 is the transportation direction 55. A portion of the transport trajectory 605 takes the article 51 into a basin 601. In some embodiments, the basin 601 may house a treatment agent 603, which may be a fluid, liquid, gas, plasma, or ionic treatment.

In some embodiments, the length of the time interval during which the article 51 receives treatment in the basin 601 can be varied by adjusting the speed of the top and bottom roller groups, or by lengthening or shortening the linear distance along which the article 51 travels in the basin 601. In some embodiments, the top roller groups and bottom roller groups move with the same linear speed at their points of contacts with the surfaces of the article 51.

To cause article 51 to move in transportation direction 55, not all the top and bottom roller groups need to be actively driven. In some embodiments, some or all of the top roller groups are actively driven while the bottom roller groups passively follow along with the movement by frictional contact with the article. In some embodiments, some or all of the bottom roller groups are actively driven while the top roller groups are passive.

In various embodiments in which treatment agent 603 is a liquid or fluid, article 51 may be completely submerged in the treatment agent 603 or only partially submerged. For example, in one embodiment only the lower surface of the article 51 is completely submerged, while the upper surface is not in contact with the treatment agent 603 at all or is only in spurious contact with the treatment agent 603.

When treatment agent 603 is a gas, both the upper surface and the lower surface of the article 51 may be exposed to the treatment agent or only one of the upper and lower surfaces of the article 51 is exposed. For example, a treatment may involve blowing a gas at one surface.

The use of a treatment agent is not required. The transport roller of FIG. 1 can be used in any process in which various different treatments, with or without a treatment agent, may be performed on the article 51. For example, in a process that uses transport rollers such as shown in FIG. 1, the article 51 may receive sonic treatment, heat treatment, or exposure to visible or invisible radiation in various intensities, or bombardment by various types of particles including electrons, ions, atoms, molecules, or other forms of matter.

Example Extensions and Alternatives

In some embodiments an article 51 may be transported in an inline process that using one or more transport rollers such as shown in FIG. 1. More than one article may be transported at the same time in an inline process in pipeline or parallel processing. The use of a linear in-line process is not required. In various embodiments, stages or phases of a process occur in a non-linear arrangement. Transport rollers may move an article from one position to another in non-linear paths. While one or more articles receive a type of treatment, one or more other articles may receive other types of treatments. Examples of treatments include, but are not limited to, electroplating, acidic, alkaline, blow drying, heating, and chemical or vapor deposition.

The roller groups in an inline process may be the same or different. For example, an inline process may use one or more transport rollers 1 of FIG. 1 only in some but not all of the top roller groups. An inline process may also use the transport roller of FIG. 1 only in some but not all of the bottom roller groups. In some embodiments, different types of transport rollers may be incorporated in the same inline process with transport rollers 1 of FIG. 1. The different types of transport rollers may or may not use coils. The transport rollers in an inline process, including transport rollers 1 of FIG. 1, do not have to be exactly the same. For example, some of the rollers may use rubber or other relatively soft types of materials for coils, while some others of the transport rollers may use relatively hard materials including metals for coils.

In some inline processes or in some portions thereof, roller groups may be relatively densely arrayed, while in some other inline processes or in some portions thereof, roller groups may relatively sparsely arrayed. In some portions of a transport trajectory 605, roller groups may be arrayed with equal distances, while in some other sections of the transport trajectory 605, roller groups may be arrayed with unequal distances.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

1. A transport roller for transporting articles, comprising:
a spindle; and
a coil on the spindle, wherein the coil comprises a flexible central section, and wherein the coil comprises a first end section and a second end section that are affixed at two opposite sides of the flexible central section to the spindle.

2-13. (canceled)

14. A transport apparatus comprising a frame, a plurality of transport rollers spaced apart and rotatably mounted in the frame, the plurality of transport rollers: comprises at least one transport roller as recited in claim 1.

15-20. (canceled)

21. A method, comprising:
providing a transport apparatus comprising a frame and a plurality of transport rollers spaced apart and rotatably mounted in the frame, at least one of the transport rollers comprising:
a spindle; and
a coil on the spindle, wherein the coil comprises a flexible central section, and wherein the coil comprises a first end section and a second end section that are affixed at two opposite sides of the flexible central section to the spindle;
transporting an article using the transport rollers.

22. The method of claim 21, wherein the coil is electrically conductive.

23. The method of claim 22, wherein the coil is electrically coupled to one of an electric current source and an electric current sink.

24. The method of claim 21, wherein the coil is electrically non-conductive.

25. The method of claim 21, wherein the flexible central section comprises three or more discrete contact areas and wherein the transport apparatus further comprises a longitudinally adjustable fixing device to adjust the number of discrete contact areas of the flexible central section.

26. The method of claim 21, wherein the transport apparatus further comprises one or more second coils each on the spindle, wherein at least one of the one or more second coils comprises a second flexible central section.

27. The method of claim 21, wherein the transport apparatus further comprises one or more second coils each on a second spindle, wherein at least one of the one or more second coils comprises a second flexible central section which.

28. The method of claim 21, further comprising providing a fluid containment vessel affixed to the frame and wherein the central section opposes a buoyancy of the article and urges the article to submerge into a fluid in the fluid containment vessel during contact of the roller with the article.

29. A product that is produced using the method in accordance with claim 21.

30. A solar panel that is produced using the method in accordance with claim 21.

31. The transport roller of claim 1, further comprising:
one of an electric current source or an electric current sink, wherein the one of an electric current source or an electric current sink is electrically connected to flexible central section of the coil.

32. The roller of claim 31, wherein the flexible central section comprises three or more discrete contact areas each electrically connected to the one of the electric current source and the electric current sink.

33. The roller of claim 31, wherein the one of the electric current source and the electric current sink is a direct-current (DC) current source or sink.

34. A method for transporting an article, comprising:
providing a coil on a spindle, wherein the coil comprises a flexible central section, and wherein the coil comprises a first end section and a second end section that are affixed at two opposite sides of the flexible central section to the spindle;
placing the article in a frictional contact with the central section of the coil; and
rotating the spindle to cause the first to exert one or more forces on the article through the frictional contact, wherein at least one of the one or more forces in a transportation direction.

35. The method of claim 34, wherein the flexible central section is electrically connected to one of an electric current source or an electric current sink.

36. The method of claim 34, wherein the one of the electric current source and the electric current sink is a direct-current (DC) current source or sink.

37. The method of claim 33, wherein the flexible central section comprises three or more discrete contact areas each electrically connected to the one of the electric current source and the electric current sink.

38. The method of claim 37, further comprising adjusting a number of the contact areas using a longitudinally adjustable fixing device that is attached to the first end section.

39. An electroplating and transporting assembly, comprising:
a transport roller that comprises a flexible central section attached to a spindle; and
one of an electric current source and an electric current sink, wherein the one of the electric current source and the electric current sink is electrically connected to flexible central section.

40. The assembly of claim 39, wherein the flexible central section comprises three or more discrete contact areas each electrically connected to the one of the electric current source and the electric current sink.

41. The assembly of claim 39, wherein the one of the electric current source and the electric current sink is a direct-current (DC) current source or sink.
